(19) United States
(12) Patent Application Publication
(10) Pub. No.: US 2013/0062492 A1
(43) Pub. Date: Mar. 14, 2013

(54) MOUNTING APPARATUS FOR STORAGE DEVICE

(71) Applicants: Hai-Tao GONG, Shenzhen City (CN); Zheng-Ming YANG, Shenzhen City (CN)

(72) Inventors: Hai-Tao GONG, Shenzhen City (CN); Zheng-Ming YANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/593,526

(22) Filed: Aug. 24, 2012

(30) Foreign Application Priority Data
Sep. 9, 2011 (CN) 201110267401.X

(51) Int. Cl. H05K 7/14

(52) U.S. Cl. 248/309.1

(57) ABSTRACT

A mounting apparatus includes a receiving member for receiving a storage device. The receiving member includes a bottom plate, two sidewalls respectively extending upwards form two opposite sides of the bottom plate, and a plurality of positioning shafts. Each sidewall has one perforation. The plurality of positioning shafts is arranged extending through the perforation, and secured in the perforation.

### BACKGROUND

1. Technical Field

The present disclosure generally relates to mounting apparatuses, and more particularly to a mounting apparatus with a bracket for a data storage device.

2. Description of the Related Art

An electronic apparatus, such as a desktop computer, tower computer, server, or the like, usually includes storage modules, such as hard disk drives, compact disk read-only memory (CD-ROM) drives, digital video disc (DVD) drives, floppy disk drives, and the like. These devices are typically added to increase the functionality of the electronic apparatus as desired by a user.

Traditional mounting apparatus for storage device includes a mesh bottom plate, two sidewalls extended upwardly from two opposite edges of the bottom plate, and an operating member engaged with the two sidewalls. The disk drive is carried by the bottom, and is secured by the two sidewalls via screws. However, the process of assembling and disassembling by screws are complex, and cost a lot of time.

Therefore, it is desirable to provide a mounting apparatus for storage device easy assembled and disassembled.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present mounting apparatus for storage device. Moreover, in the drawings, like reference numerals designate corresponding parts throughout the views.

FIG. 1 is an assembled, isometric view of a mounting apparatus and a storage device in accordance with an embodiment of the disclosure.

FIG. 2 is an exploded view of the mounting apparatus of FIG. 1.

FIG. 3 is an enlarged view of a positioning shaft of the mounting apparatus of FIG. 2.

### DETAILED DESCRIPTION

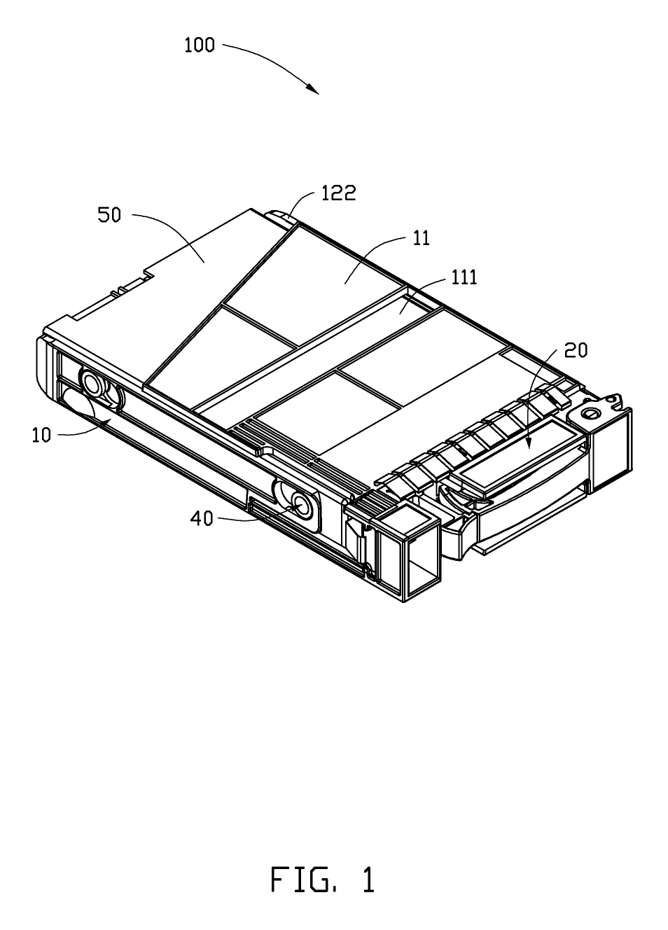

Referring to FIG. 1, a mounting apparatus 100 in accordance with an exemplary embodiment is provided. The mounting apparatus 100 includes a receiving member 10 for receiving a storage device 50, an operating member 20 connected to the receiving member 10 and a plurality of positioning shafts 40.

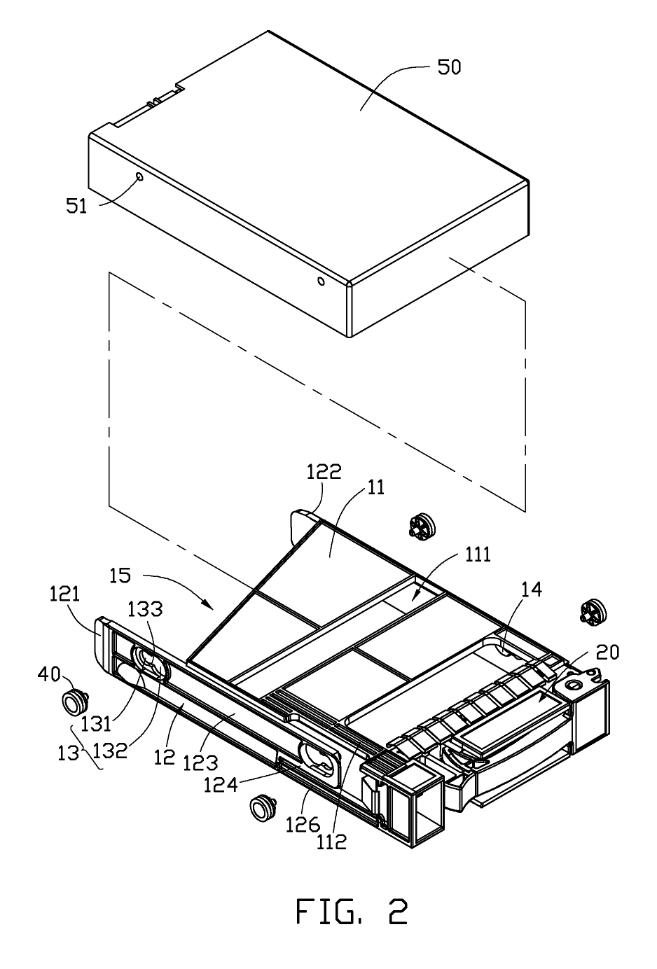

Specifically, referring to FIG. 2, the receiving member 10 includes a bottom plate 11, and two sidewalls 12 respectively extending upwards from two opposite sides of the bottom plate 11. An opening 111 is defined in the bottom plate 11 and vertical to the sidewalls 12. The bottom plate 11 is spaced to the operating member 20. A lath 112 extends toward the operating member 20 from a side of the bottom plate 11 near one of the sidewalls 12 to connect the operating member 20.

The sidewalls 12 include a first sidewall 121 and a second sidewall 122 parallel to the first sidewall 121. The first sidewall 121 and the second sidewall 122 are substantially rectangular. The first sidewall 121 includes a middle section 123, an elastic section 124 extending towards the operating member 20 from an end of the middle section 123 and a free section 125 at another end opposite to the elastic section 124. The bottom plate 11 connects the middle section 123 and the second sidewall 122. A width of the bottom plate 11 near the middle section 123 is less than that of the bottom plate 11 near the second sidewall 122.

The first sidewall 121 has a top edge 126 near the elastic section 124. The elastic section 124 is interval with the bottom plate 11 and the top edge 126 of the first sidewall 121. The elastic section 124 could be deformed relatively by external force.

The first sidewall 121 defines two perforations 13 at the elastic section 124 and the free section 125, respectively. Each of the perforations 13 is gourd shaped. The perforation 13 in the elastic section 124 is arranged axisymmetrical with the perforation 13 on the free section 125. Each perforation 13 includes a fixing hole 131 and a guiding hole 132 interconnected with the fixing hole 131. A diameter of the guiding hole 132 is greater than that of the fixing hole 131. A pair of flanges 133 extends oppositely at an inner surface of the perforation 13 and located between the fixing hole 131 and the guiding hole 132.

The second sidewall 122 defines two perforations 14 corresponding to the two perforations 13 on the first sidewall 121. Each of the perforations 14 is gourd shaped. The perforation 14 on the second sidewall 122 has a configuration same as the perforation 13 on the first sidewall 121.

The operating member 20 is connected with the top edge 126 of the first sidewall 121, the lath 112 and one end of the second sidewall 122 for attaching the mounting apparatus 100 and the storage device 50 to related electronic device (not shown).

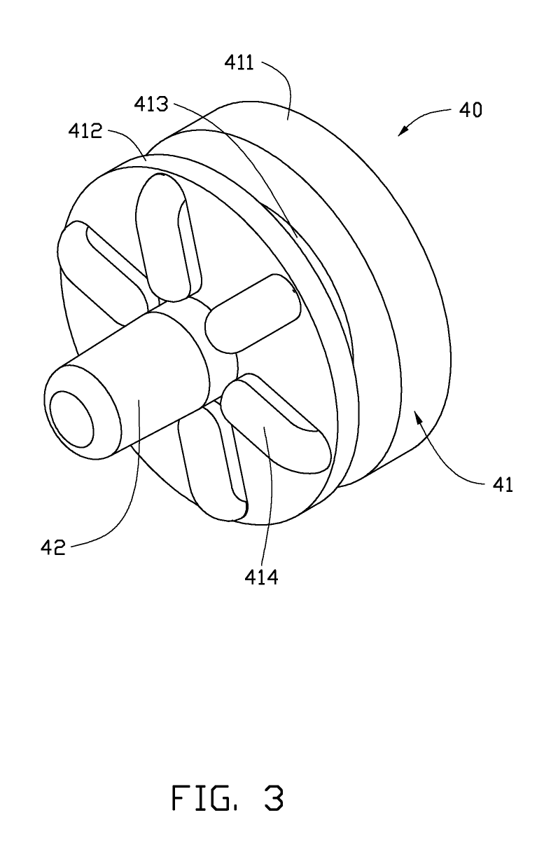

Referring to FIG. 3, each positioning shaft 40 includes a latching portion 41 and an extending column 42 extended outwardly from the latching portion 41.

Specifically, the latching portion 41 includes a first latching plate 411, a second latching plate 412 and a connecting column 413 between the first latching plate 411 and the second latching plate 412. The first latching plate 411 and the second latching plate 412 have a circular shape with a thickness. A diameter of each of the first and second latching plates 411, 412 is equal to that of the guiding hole 132. The connecting column 413 has a cylindrical shape with a diameter equal to that of the fixing hole 131. A plurality of protrusions 414 is disposed at a surface adjacent to the extending column 42. The protrusions 414 can strengthen the stability of the positioning shafts 40.

The extending column 42 extends from the second latching plate 412 along a direction away from the first latching plate 411. The extending column 42 is cylindrical.

When the mounting apparatus 100 and the storage device 50 are assembled, the positioning shafts 40 are latched at the receiving member 10. Specifically, the extending column 42 of the positioning shafts 40 and the second latching plate 412 extend through the guiding hole 132 of the first and second sidewall 121, 122. Then the positioning shaft 40 is moved toward the fixing hole 131. The connecting column 413 is latched in the fixing hole 131 and positioned by the flanges 133. The first and second latching plates 411, 412 are located two sides of the flanges 133 respectively.

Since the diameter of the first and second latching plates 411, 412 are greater than that of the fixing hole 131, the latching portion 41 of the positioning shaft 40 are secured in the fixing hole 131.

After that, the storage device 50 is received in the receiving member 10. Specifically, two side surfaces of the storage device 50 define a plurality of positioning holes 51. One side of the storage device 50 is putted into the receiving member 10. The side of the storage device 50 is resisted the inner surface of the second sidewall 122. While the extending columns 42 of the positioning shafts 40 on the second sidewall 122 are embedded in the positioning holes 51 of the storage device 50. Then the elastic section 124 of the first sidewall 121 is deformed outwardly from an intended position thereof along the direction away from the second sidewall 122. Another side of the storage device 50 is pressed toward the receiving member 10 so that a positioning hole 51 corresponding to the elastic section 124 is target with an extending column 42 of the positioning column 40 corresponding to the elastic section 124. The elastic section 124 of the first sidewall 121 is released to migrate back. The extending column 42 is embedded into the positioning hole 51.

Then the extending column 42 located at an end of the first sidewall 121 away from the operating member 20 is embed into corresponding positioning hole 51 of the storage device 50 by same way.

Finally, the storage device 50 is received in the receiving member 10 by above method. The storage device 50 is secured by the positioning column 40.

Further more, the positioning column 40 can be made from rubber materials. The positioning column 40 can buffer external force after the extending column 42 is embedded in the positioning hole 51 of the storage device 50.

Alternatively, the diameter of the first latching plate 411 of the positioning column 40 can be greater than that of the guiding hole 132. The diameter of the second latching plate 412 is between that of the fixing hole 131 and the guiding hole 132.

Since the mounting apparatus 100 includes a bottom plate 11 for supporting the storage device 50. A number of positioning columns 41 extend through and are latched in the perforation 13. The positioning columns 40 are embedded in the positioning hole 51 of the storage device 50. So that the storage device 50 is received in the receiving member 10. The mounting apparatus 100 is assembled or disassembled without screws and other external tool, the process of assembling and disassembling is simple and efficient.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. A mounting apparatus, comprising:
a receiving member, the receiving member comprising a bottom plate, a first sidewall and a second sidewall respectively extending upwards form two opposite sides of the bottom plate, and a plurality of positioning shafts, each of the first sidewall and the second sidewall having a perforation, the plurality of positioning shafts being arranged extending through the perforation, and being secured in the perforation; and
the perforation comprising a fixing hole and a guiding hole interconnected each other, a diameter of the guiding hole being greater than that of the fixing hole.

2. The mounting apparatus of claim 1, wherein a pair of flanges are defined oppositely at an inner surface of the perforation and located between the fixing hole and the guiding hole.

3. The mounting apparatus of claim 1 further comprising an operating member connected the first and second sidewalls, wherein an end of the first sidewall adjacent to the operating member comprises an elastic section, and the perforation is located at the elastic section.

4. The mounting apparatus of claim 3, wherein the first sidewall is made from flexible materials.

5. The mounting apparatus of claim 2, wherein a width of the bottom plate near the first sidewall is less than that of near the second sidewall.

6. The mounting apparatus of claim 5, wherein an opening is defined in the bottom plate, and the opening is vertical to the first sidewall and the second sidewall.

7. The mounting apparatus of claim 1, wherein each of the positioning shafts comprises a latching portion, the latching portion comprises a first latching plate, a second latching plate and a connecting column connecting the first latching plate and the second latching plate, the first latching plate and the second latching plate are located at two sides of the fixing hole , and the connecting column is latched in the fixing hole.

8. The mounting apparatus of claim 7, wherein the first latching plate is circular, and a diameter of the first latching plate is greater than that of the guiding hole.

9. The mounting apparatus of claim 7, wherein the second latching plate is circular, and a diameter of the second latching plate is between that of the fixing hole and the guiding hole.

10. The mounting apparatus of claim 7, wherein diameters of the first and second latching plate are equal to that of the guiding hole.

11. The mounting apparatus of claim 7, wherein a diameter of the connecting column is equal to that of the fixing hole.

12. The mounting apparatus of claim 7, wherein each of the positioning shafts further comprises an extending column, and the extending column extends from the second latching plate along a direction away from the first latching plate.

13. The mounting apparatus of claim 12, several protrusions are disposed at a surface of the second latching plate adjacent to the extending column.
